(19) United States
(12) Patent Application Publication
(10) Pub. No.: US 2019/0115533 A1
(43) Pub. Date: Apr. 18, 2019

(54) METHOD FOR THE PRODUCTION OF LAYERS OF RERAM MEMORIES, AND USE OF AN IMPLANTATION DEVICE

(71) Applicant: Forschungszentrum Juelich GmbH, Juelich (DE)

(72) Inventors: Rene Borowski, Juelich (DE); Won Joo Kim, Sunnyvale, CA (US); Vikas Rana, Juelich (DE); Rainer Waser, Aachen (DE)

(21) Appl. No.: 16/090,594

(22) PCT Filed: Mar. 31, 2017
(86) PCT No.: PCT/DE2017/000080

§ 371 Date: Oct. 2, 2018

(30) Foreign Application Priority Data
May 4, 2016 (DE) 10 2016 005 537.5

(51) Int. Cl. H01L 45/00

(52) U.S. Cl. CPC H01L 45/165; H01L 45/08; H01L 45/147; H01L 45/145; H01L 45/146; H01L 45/1233

(57) ABSTRACT

A method for producing layers of ReRAM memories includes applying a TMO layer to a lower electrode, and implanting, via ion implantation, impurity atoms in the TMO layer.

### CROSS REFERENCE TO RELATED APPLICATIONS

This application is a U.S. National Stage Application under 35 U.S.C. § 371 of International Application No. PCT/DE2017/000080 filed on Mar. 31, 2017, and claims benefit to German Patent Application No. DE 10 2016 005 537.5 filed on May 4, 2016. The International Application was published in German on Nov. 9, 2017 as WO 2017/190719 A1 under PCT Article 21(2).

### FIELD

The invention relates to a method for producing layers of ReRAM memories, and to the use of an implanter.

### BACKGROUND

According to the prior art, non-volatile data memories, such as ex-flash memories, exist, by means of which information can be permanently stored. However, for these memories, limits of miniaturization are reached, which creates the need for non-volatile memory media that have smaller dimensions. Because the currently available charge-based memories (ex-flash memories) will have reached the physical limits of miniaturization in the near future, new memory concepts are necessary.

ReRAM memories are composed of two opposite electrodes, between which transition metal oxide (TMO) layers are stacked. TMO layers may have an active, electrically conductive layer region or be continuously active and electrically conductive, or have a passive, non-electrically conductive layer region or be passive and electrically insulating. In particular, resistive random-access memories (ReRAMs), among other non-volatile memory forms, are considered to be a successor to the current charge-based memory cells. However, there are some technical challenges to overcome, such as, e.g., damage of the component during the application of the necessarily high forming voltage, which can destroy adjacent memory cells in the passive array as a result of undesirably high current flashovers, a narrow reading tolerance (Iₒₙ/I_{off}) in low-voltage operation, and high efficiency to be achieved for the components below 20 nm in size.

It is known that the control of the oxygen ion or vacancies profile within the transition metal oxide (TMO) layer is the key to improving the performance of ReRAM. For example, numerous approaches to methods have been made for producing the TMO layers using deposition methods and element doping.

A special, active oxide-switching layer is known of which the material has been specifically pretreated by element doping, and in which nano-crystals are inserted, i.e. embedded within a special switching layer (nc-TiO2). This structure is located between two metal electrodes. Such ReRAMs are known from the documents U.S. Pat. Nos. 8,569,172, 8,546,781, 8,441,835, US2013/0089949, US2014/0302659, U.S. Pat. No. 8,791,444, US2013/0187116, US2015/0034898, U.S. Pat. Nos. 8,835,890, 8,487,290 and 8,907,313.

Corresponding ReRAMs can also be obtained by thermal methods, in which TMO layers can be produced by thermal annealing between 200° C. and 800° C. with various gases, which layers have desired properties.

The first method requires a forming step, which is energy-intensive, since high voltages must be generated and device components produced on the ReRAMs that provide for the forming, namely voltage regulators and voltage generators, which components must be precisely manufactured, but are used only once for forming. This consumes materials for components of the ReRAMs and causes costs.

The second method is performed at high temperatures, also consumes energy during thermal annealing (200° C.˜800° C.) with various gases. This requires a heat treatment step (200° C.˜800° C.) in order to activate the process gas (for example NH₃, N₂, O₂, O₃, H₂O, Cl₂, Ar, H₂, N₂O, SiH₄, CF₄) within the active switching oxide layer. It would be better for heat treatments at a high temperature to be avoided as much as possible, because said treatments damage the CMOS performance. In addition, it is also still difficult to control the oxygen ions or nitrogen ions and vacancies in terms of location and quantity. Thermal methods of this type are disclosed in the document US 2013/0336041 and U.S. Pat. No. 8,913,418.

### SUMMARY

In an embodiment, the present invention provides a method for producing layers of ReRAM memories. The method includes applying a TMO layer to a lower electrode, and implanting, via ion implantation, impurity atoms in the TMO layer.

### BRIEF DESCRIPTION OF THE DRAWINGS

The present invention will be described in even greater detail below based on the exemplary figures. The invention is not limited to the exemplary embodiments. All features described and/or illustrated herein can be used alone or combined in different combinations in embodiments of the invention. The features and advantages of various embodiments of the present invention will become apparent by reading the following detailed description with reference to the attached drawings which illustrate the following:

FIG. 1a shows a cell resulting from method steps according to an embodiment of the invention;

FIG. 1b shows experimental comparison data for a cell according to FIG. 1a;

FIG. 2a shows another cell resulting from the method steps;

FIG. 2b shows experimental comparison data for a cell according to FIG. 2a;

FIG. 2c shows experimental comparison data for a cell according to FIG. 2a; and

FIG. 3 shows examples of cells with layer sequences which have been produced by a method according to an embodiment of the invention.

### DETAILED DESCRIPTION

Embodiments of the invention provide methods for producing ReRAMs, which save energy and electrical components, by which costs are reduced and process gases are saved. Forming and associated damage of the ReRAM memory or thermal methods should be avoided. The CMOS performance should not be reduced. In particular, it should be possible to control oxygen ions or nitrogen ions and vacancies in the TMO layers in terms of location and quantity. Further miniaturization of the ReRAMs should be made possible. The reading tolerance should be increased in low-voltage operation. The efficiency of the components below 20 nm should be increased. Embodiments of the invention further provide devices by way of which such methods can be carried out, and the advantages of the methods achieved.

With methods according to embodiments of the invention and the use of devices according to embodiments of the invention, it is possible to save energy and materials and thus to reduce costs. The CMOS performance is not reduced. It is possible in the TMO layers to control oxygen and nitrogen ions or other ions in terms of location and quantity. Methods according to embodiments of the invention enable the miniaturization of ReRAMs. The efficiency of the components below 20 nm is increased.

The ReRAM memories according to embodiments of the invention have an upper electrode and a lower electrode.

The upper and lower electrodes can be made of the same material, which is referred to as a symmetrical structure, or made of different materials, which is referred to as an asymmetrical structure.

In the symmetrical structure, both electrodes may be made of Pt, Ti, Ta, TiN, Hf, Al or W.

In the asymmetrical structure, for the upper/lower combination, the material combination Pt/Ti, Pt/Ta, Pt/TiN, Pt/Hf, Pt/Al, Pt/W, Ti/Pt, Ti/Ta, Ti/TiN, Ti/Hf, Ti/Al, Ti/W, Ta/Pt, Ta/TiN, Ta/Hf, Ta/Al, Ta/W, TiN/Pt, TiN/Ti, TiN/Ta, TiN/Hf, TiN/Al, TiN/W, Hf/Pt, Hf/Ti, Hf/Ta, Hf/TiN, Hf/Al, Hf/W, Al/Pt, Al/Ti, Al/Ta, Al/TiN, Al/Hf, Al/W , W/Pt, W/Ti, W/Ta, W/TiN, W/Hf or W/Al can be used, wherein the first element is the material for the lower electrode and the second element is the material for the upper electrode.

The upper and lower electrodes can have layer thicknesses of 25 nm to 100 nm, preferably 30 nm to 50 nm.

In methods according to embodiments of the invention, at least one TMO layer is applied to the lower electrode in each case. In this case, all TMO layers known to a person skilled in the art can be applied. For example, for the TMO layers, materials consisting of a component from the group consisting of hafnium oxide, tungsten oxide, aluminum oxide, aluminum oxide nitride, titanium oxide, tantalum oxide, nickel oxide, niobium oxide, magnesium oxide, cobalt oxide, germanium oxide, molybdenum oxide, silicon oxide, silicon nitride, tin oxide, zirconium oxide, cerium oxide, zinc oxide, copper oxide, strontium titanate can be applied.

The stoichiometry of the composition of the sputtered TMO layers proves to be not always sharply defined in practice. They can contain oxygen and/or nitrogen atoms. For example, Al₂O₃, HfOₓ, HfO₂, HfO, HfOₓN_{y}, HfₙOₓ, W₂O₃, WO₃, TiOₓ, TiO₂, Ti₂O₃, TaOₓ, Ta₂O₅, TaON, NiO, Nb₂O₅, MgO, CoO, WₙOₓ, TiₙOₓ, TaₙOₓ, SnO₂, ZrₓO_{y}, ZrO, GeOₓ, CeO₂, ZnO, WO, CuO₂, SrTiO₃, MoO, AlOₓN_{y}, AlₙOₓ, SiₓN_{y} can be sputtered as a TMO layer. Methods according to embodiments of the invention are, in principle, not limited to certain materials for TMO layers.

In a cell, all TMO layers may consist of the same material, preferably a component from the group of the materials mentioned in the preceding paragraph. In multilayered cells having at least two TMO layers, at least two TMO layers can consist of different materials, preferably materials from the group of the materials mentioned in the preceding paragraph.

The stoichiometric numerical ratios of metal to oxygen can also be broken, so that they do not correspond to any composition which results from the charge ratios of the ions.

A TMO layer may have a thickness of 1.5 nm-10 nm in the case of a thin TMO layer.

A thick layer can be between > 10 nm, for example 10.1 nm, and 40 nm.

There are typical embodiments in which only one layer is applied between the lower and upper electrodes. This layer may have a thickness, for example, of 1.5 nm-40 nm.

Also, thin and thick layers can be applied to the lower electrode in a layer sequence.

If at least two TMO layers are applied to the lower electrode, these are preferably thin, and each have a thickness of 5 nm-10 nm.

The number of TMO layers can be arbitrarily selected and may be, for example, between one and five TMO layers.

The thickness of the individual TMO layers in a layer sequence is also arbitrarily selectable.

Each individual TMO layer can be applied to the lower electrode by methods known to a person skilled in the art.

For example, the TMO layers can be sputtered by a reactive PVD method (physical vapor deposition). Alternatively, a reactive ALD method (atomic layer deposition method) or a reactive CVD method (chemical vapor deposition method) can be used. A reactive method is understood to be a method in which the applied metal layer is oxidized with oxygen.

According to embodiments of the invention, in at least one TMO layer, impurity ions, such as oxygen ions, for example O⁺, O²⁺, or nitrogen ions, for example N⁺, N₂⁺, are introduced into the TMO layer by an ion implantation method. Ion implantation is a method for introducing impurity atoms (in the form of ions), which are shot at the layer to be implanted. Furthermore, the implantation of elements with cations of elements Li, Be, B, C, F, Ne, Na, Mg, Al, Si, P, S, Cl and Ar is possible. The charge of the cations depends on the conditions under which they are formed. As a result, in the corresponding TMO layer, there are hardly any ions or no ions, but oxygen atoms, nitrogen atoms or atoms of another element.

In principle, all known ion implantation methods and ion implantation devices can be used.

Which and how many TMO layers are implanted with oxygen ions, nitrogen ions, or other ions is left to the discretion of a person skilled in the art. It may be that one, several or all TMO layers are implanted with oxygen ions, nitrogen ions or other ions.

In a ReRAM memory, either all TMO layers treated by ion implantation can be implanted with oxygen ions or all TMO layers treated by ion implantation can be implanted with nitrogen ions or other ions, so that a ReRAM memory contains only oxygen-implanted layers, only nitrogen-implanted layers or only layers implanted with another ion type.

However, within a ReRAM memory, TMO layers may also be present in which different elements are implanted.

For the ion implantation, various methods are known which can be used in principle.

An implanter, for example an ion gun, can be used, by means of which the oxygen ions, nitrogen ions or other ions are accelerated.

In this embodiment, the TMO layer to be treated is in a vacuum chamber, and is bombarded with oxygen ions, nitrogen ions or other ions.

The energy for these ions is preferably 0.5 keV to 200 keV. At these energy levels, the oxygen ions, nitrogen ions or other ions reach velocities which result in ion implantation of the TMO layer, without this resulting in excessive removal of TMO molecules.

In this case, an ion density of 10⁸ ions per cm² to 10¹⁸ ions per cm² can be achieved.

The gas flows of oxygen, nitrogen or other gases which are preferably to be used are at 1 sccm (standard cubic centimeters=1 cm³ at T=0° and p=1013.25 hPa), and 100 sccm.

In ion implantation methods, it is important that the ion currents are directed to the TMO substrate. For this purpose, so-called ion optics are used, with which it is possible to direct ion currents to surfaces. In this case, a plasma which contains the desired ions is first generated. The plasma can contain the cations of the above-mentioned materials. The ions of the plasma are subjected to an acceleration which is directed to the surface of the TMO layer. For this purpose, anode grids can be used. For example, 1-3 anode grids can be used, which are arranged preferably perpendicularly or substantially perpendicularly to the ion current, with respect to the target direction of the ions. In this case, it is important that the ion beam is directed such that it hits the surface as homogeneously as possible, with respect to its cross-sectional surface, so that a uniform implantation is carried out. In this case, the ion current passes through, in an embodiment with two anode grids, an output voltage, which aligns the ion current in one direction and then an acceleration voltage, which accelerates the ion current to the desired kinetic energy. The ion currents directed in this way can then impinge on the uppermost TMO layer.

In this case, it is usual that the accelerated oxygen ions, nitrogen ions or other ions are at least partially neutralized by a neutralizer, thus no positive charge cloud is formed during the impingement of the ions in the vicinity of the TMO layer to be implanted, which prevents or reduces the penetration of ions or oxygen or nitrogen atoms into the TMO layer to be implanted.

For this purpose, an electron source, for example a cathode laterally mounted over the TMO layer, can be available above the TMO layer, which source emits electrons into the region of the surface of the TMO layer.

There are ion implantation devices known in the prior art which can be used. These are known implanters or, with appropriate process control, for example as described above, reactive ion beam etchers (RIBE).

With the ion implantation, at least one layer of the TMO materials mentioned at the outset can be treated. The number of TMO layers, their chemical composition and their sequence, as well as the individual layer thicknesses, can be selected arbitrarily.

Various embodiments of ion implantation into a TMO layer are possible.

A TMO layer may be implanted over its entire layer thickness with the above-mentioned ions or elements.

However, a TMO layer may also be implanted only up to a certain penetration depth with ions or elements.

The penetration depth of the ions in the TMO layer to be treated can be controlled by the kinetic energy. However, it also depends on the material of the TMO layer to be treated by the implantation. Thus, the atomic mass of the cations of the TMO layer and thus the space-filling of the atoms and the grid properties of the TMO layer have an influence on the penetration depth of the atoms of the elements to be implanted. Therefore, the experimental parameters for the implantation must be selected by a person skilled in the art according to the desired results. This is within the capabilities of said person skilled in the art.

The implanted part of a TMO layer is the active, electrically conductive layer of the TMO layer. The unimplanted part of the TMO layer is the passive, electrically insulating part of the TMO layer.

A cell consisting of a lower electrode of at least one TMO layer and an upper electrode may be differently composed.

Within a cell, all TMO layers, or at least one TMO layer, can be active, i.e., electrically conductive, so that they are suitable for a switching function, or a layer region, corresponding to the penetration depth of the importation, can be active and thus electrically conductive.

Within a cell, at least one TMO layer can, however, also be completely passive and thus electrically insulating, such that no ions have been imported into this TMO layer.

How exactly the sequence and composition of TMO layers are designed in a cell depends on the desired property of the cell and can be arbitrarily configured.

The TMO layer located on the lower and/or upper electrode should be passive at least on the side facing the electrode. But, it can also be passive over its entire layer thickness. The TMO layer adjacent to the electrodes may not be an insulator; however, the resistance must be such that a short circuit does not occur.

Particularly thin TMO layers can be implanted with oxygen ions, nitrogen ions or other ions in the specified parameter ranges of kinetic energy in the range of 0.5 keV to 200 keV.

If a thin layer has a thickness of 1.5 nm-10 nm, the implantation can be carried out, for example, for up to half the thickness. The depth of implantation can be selected arbitrarily, depending on requirements, and depends on the implantation energy.

It is also possible that thick TMO layers of a thickness of > 10 nm-40 nm are bombarded at higher energy levels, wherein the total layer thickness is implanted with oxygen ions, nitrogen ions or other ions.

The penetration depth of the importation of the elements determines the memory duration, the switching speed, the efficiency or also the duration of the memory capacity of the cell.

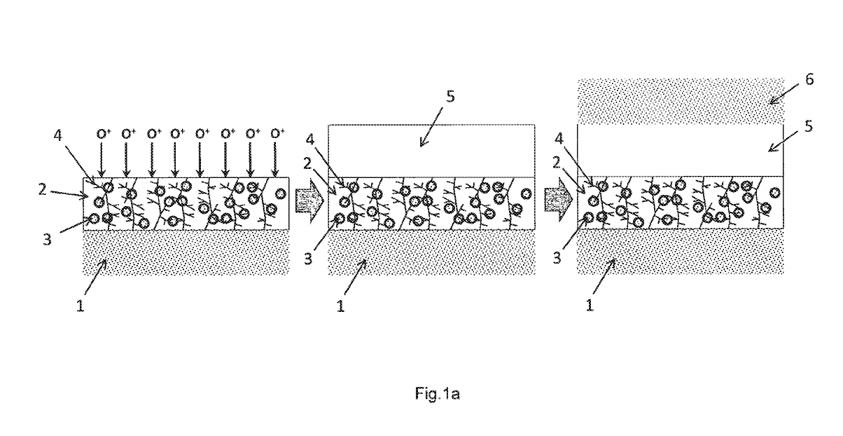

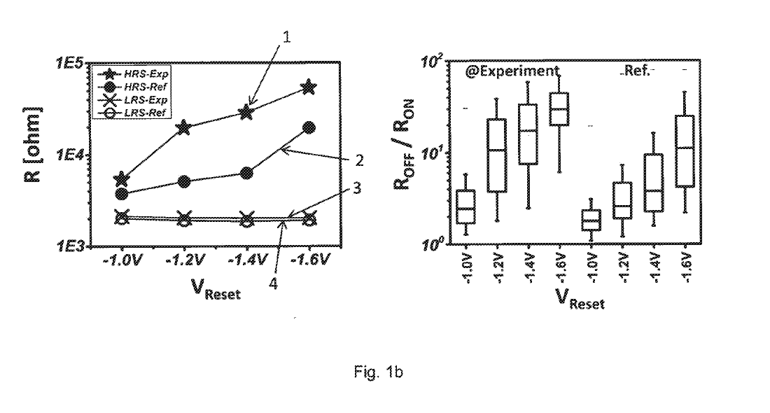

FIG. 1a shows a lower electrode 1 on the left-hand side, on which a TMO layer 2 is located, on which oxygen ions 3 act, which are shown in the TMO layer as circles and lead to oxygen vacancies 4, which are shown as branched arms. In addition, another stage of the cell can be seen in the middle, which has another TMO layer 5 which has not been treated by ion implantation. On the right-hand side, a completed cell is shown, in which the upper electrode 6 is applied.

FIG. 1b shows experimental comparison data between cells that have been produced by a method according to the invention according to FIG. 1a and cells according to the prior art.

On the left-hand side of the figure, a graph is shown in which the resistance of a cell in ohms is plotted against the reset voltage V_{Reset}. The curve 1 shows the dependency of the resistance of a cell according to an embodiment of the invention as a function of the applied reset voltage V_{Reset}. Curve 2 shows the dependency of the resistance of a cell according to the prior art on the reset voltage V_{Reset}. It can be recognized that the cell produced according to the embodiment of the invention has a wider bandwidth of the resistance by comparison with the prior art even at lower values for the reset voltage V_{Reset}. Below these curves, the curves 3 and 4 are shown. In this case, the curve 3 indicates the data for a cell according to an embodiment of the invention for the low resistance state, and the curve 4 indicates the data for the low resistance state of a cell according to the prior art.

On the right-hand side of FIG. 1b, the ratio between the resistance for the state 1 to the state 0 for various reset voltages V_{Reset} in volts is shown. On the left-hand side of this figure, the value range for cells produced by a method according to an embodiment the invention is shown; on the right-hand side, the value range for cells according to the prior art is shown. The size of the box shows the distribution of the measured values between 25% and 75% of the measured values. The horizontal line in the boxes shows the median value. The extension lines of the boxes represent 5% to 95% of the measured values. In comparison, it can be seen that the cells which have been produced by the method according to the embodiment of the invention, at the same reset voltages V_{Reset}, has a higher quotient for the ratio between the values of the resistance for the states 1 and 0.

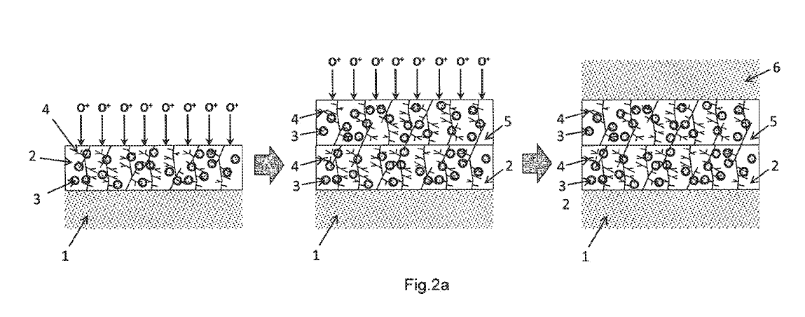

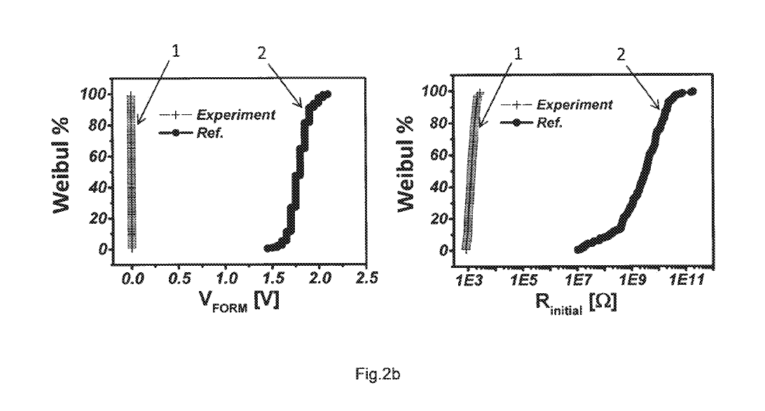

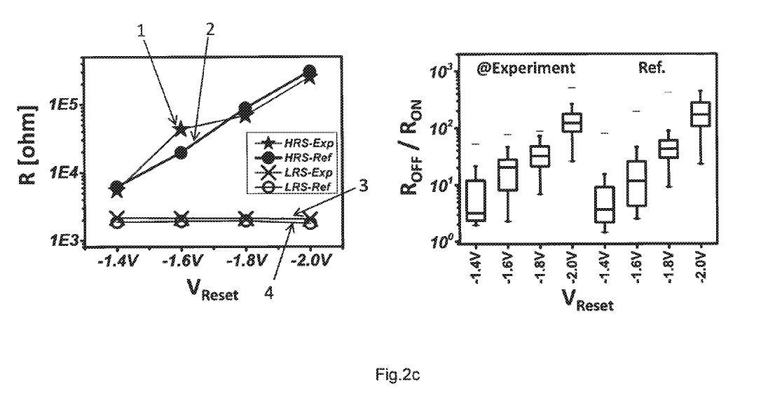

In FIG. 2a, the same components of the cell have the same reference numerals. The left-hand part of the figure is identical to that in FIG. 1a. The middle part of the figure shows a second TMO layer 5 which is treated with injected oxygen ions 3.

FIG. 2b shows, in the left-hand part of the figure, experimental comparison data between cells that have been produced by a method according to an embodiment of the invention according to FIG. 2a and cells according to the prior art, for 50 cells which have been measured in each case. The forming voltage is the abscissa in this representation, and the Weibull distribution function in % is the ordinate. In the graph, curve 1 corresponds to a cell produced according to an embodiment of the invention, and curve 2 to a cell according to the prior art. It shows, for these cells, the percentage quantity of switched cells at a predetermined forming voltage V.

On the right-hand side of FIG. 2b, the number of cells that have reached a certain resistance is shown, depending on the initial resistance. Here, the abscissa is the initial resistance of a cell in ohms and the ordinate is the Weibull distribution in %. Curve 1 again indicates the values for the cell according to an embodiment of the invention. Curve 2 shows the values for cells for the example in FIG. 2a according to the prior art. It can be seen that no forming voltage is needed for a cell produced according to the embodiment of the invention.

FIG. 2c shows experimental comparison data between cells that have been produced by a method according to an embodiment of the invention according to FIG. 2a and cells according to the prior art.

On the left-hand side of the figure, a graph is shown in which the resistance of a cell in ohms is plotted against the reset voltage V_{Reset}. The curve 1 shows the dependency of the high-impedance resistance of a cell according to an embodiment of the invention as a function of the applied reset voltage V_{Reset}. Curve 2 shows the dependency of the high-impedance resistance of a cell according to the prior art on the reset voltage V_{Reset}. Below these curves, the curves 3 and 4 are shown. In this case, the curve 3 indicates the data for a cell according to an embodiment of the invention for the low-resistance state, and the curve 4 indicates the data for the low-resistance state of a cell according to the prior art.

On the right-hand side of FIG. 2c, the ratio between the resistance for the state 1 to the state 0 is shown for various reset voltages in volts. On the left-hand side of this figure, the value range for cells produced by a method according to an embodiment of the invention is shown; on the right-hand side, the value range for cells according to the prior art is shown. The size of the box shows the distribution of the measured values between 25% and 75% of the measured values. The horizontal line in the boxes shows the median value. The extension lines of the boxes represent 5% to 95% of the measured values.

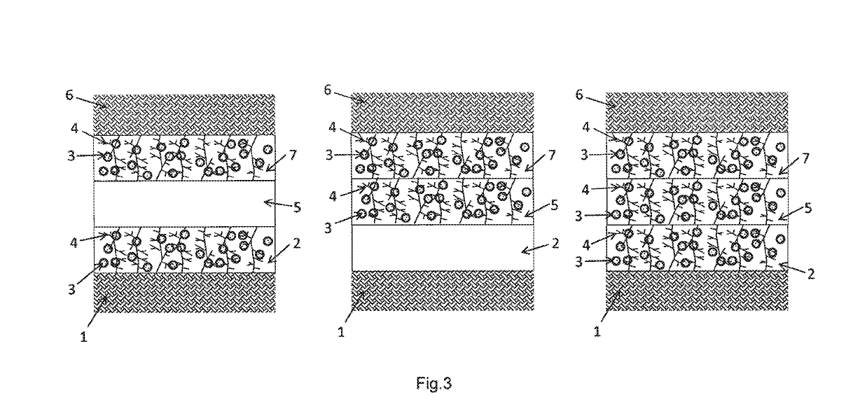

FIG. 3 shows three examples of cells which have been produced according to a method according to an embodiment of the invention. Said figure includes a third TMO layer 7.

### EXAMPLES

Experiments were carried out in an ion beam etching installation from Oxford (Oxford lonfab 300 plus). This installation was neither modified nor rebuilt. The basic function of the etching system is the physical dry etching method. In this case, the surface of the substrate is etched by the bombardment of ions. The bombardment results in the sputtering of the substrate material; in this case, the previous processes are similar to those in cathode sputtering, which is not counted among the dry etching methods. In principle, in highly simplified terms, this relates to an “atomic sandblaster”.

It has been found that, as a side effect of the ion beam etching, an implantation of ions, for example oxygen ions or nitrogen ions, can take place by means of the oxygen ion beam or the nitrogen ion beam at low energy.

The etching is carried out in a high-vacuum chamber, in order to prevent interactions, such as scattering of the particle beam by the residual gas atoms of the vacuum. The ion beam has a diameter of 150 mm and is coherent, in order to obtain the same ion density in as many regions of the substrate as possible and thus a homogeneous etching effect. The obtained etching profile is anisotropic (directed).

To generate the ion beam, first, a gas (e.g., Ar, O2 or N2) in a high-frequency alternating field, of which the frequency is typically 13.56 MHz, is brought to excitation. The ions thus generated are, at the same time, both accelerated toward the substrate by means of an ion optics, in this case two grids, and brought into coherence. In order to keep the free, mean path length of the ions as long as possible, the etching process is carried out at approx. 4×10⁻⁴ mBar, depending on the used gas flows.

In order to prevent a positive space charge from being formed on a non-conductive substrate by the incoming ions, an electron beam penetrates the ion beam, after said ion beam has passed through the ion optics, in this case the grid, perpendicularly to the movement direction. The electrons neutralize the positively charged gas ions, so that they can no longer emit a positive space charge when impinging on the substrate. If no neutralization takes place, a positive electric field would very quickly build up over the substrate and deflect the positively charged ions.

The kinetic energy of the gas atoms is also converted, inter alia, into thermal energy upon impingement. In order to protect the substrates from the thermal influences, substrate cooling can be carried out, for example with helium gas, on the rear face thereof.

The 1st TMO layer (Ta2O5, which is deposited on the surface of the lower electrode) already has an oxygen-ion implantation. But, the 2nd TMO layer (Ta2O5, arranged between the 1st TMO layer and the upper electrode) has received NO oxygen-ion implantation; see FIG. 1(a). Thus, there are two TMO layers between the upper and the lower electrodes. A significant improvement in reading tolerance (R_{off}/Rₒₙ) is observed in the test components (with oxygen-ion implant only in the 1st TMO layer) over all RESET voltage conditions of −1.0 V to −1.6 V; see FIG. 1(b).

If both the 1st TMO layer and the 2nd TMO layer have already received oxygen-ion implantation (see FIG. 2(a)) a forming step is no longer needed, whereas the reference components (doubled TMO layer WITHOUT oxygen-ion implantation) need more than +1.8 V forming voltage; (see FIG. 2(b)).

All of the measured test components have low resistance states (˜1.4 k ohm) before the forming step, whereas the reference components exhibit a fairly high resistance (> 12 G ohm). The oxygen vacancies intentionally created by oxygen-ion implantation cause a good conducting path between the upper and the lower electrodes prior to forming. Therefore, the component with the double-ion implant TMO layer could have a lower resistance state without a forming step. FIG. 2(c) shows the comparison of the electronic performance between the test components and reference components. There is no drop in the observed behavior in the test components.

Based on these experimental results, various types of advantages can be gained, depending on the location of the oxygen-ion implantation. Depending on the application of the ReRAM components, the position of the oxygen ions and vacancies can be put within a specific TMO layer in a targeted manner. FIG. 3 shows examples of variations of the components produced by oxygen-ion implantation, whereby the produced individual layers were obtained with oxygen ions and oxygen vacancies, which were controlled in a targeted manner in terms of location and quantity.

Since the basic principles of the ion implantation (ion injection and vacancy formation) are applicable to all types of TMO layers, such as HfOx, WOx, AlOx, etc., there is no limit to the TMO material selection for the ReRAM component design. Thus, this gives a great deal of flexibility to improve the performance of the components, depending on the desired application.

Each single TMO layer could be made of the same TMO material (homo multi TMO) or different TMO materials (hetero multi TMO).

Instead of oxygen-ion implantation, nitrogen-ion implantation can be used. Oxygen or nitrogen doping are also possible as plasma-assisted process steps, in order to be able to put the oxygen or nitrogen ions in a TMO layer.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A method for producing layers of ReRAM memories, the method comprising:
applying a TMO layer to a lower electrode; and
implanting, via ion implantation, impurity atoms in the TMO layer.

2. The method according to claim 1, wherein the TMO layer includes one component from the group of hafnium oxide, tungsten oxide, aluminum oxide, aluminum oxide nitride, titanium oxide, tantalum oxide, nickel oxide, niobium oxide, magnesium oxide, cobalt oxide, germanium oxide, molybdenum oxide, silicon oxide, silicon nitride, tin oxide, zirconium oxide, cerium oxide, zinc oxide, copper oxide, strontium titanate.

3. The method according to claim 2, wherein the TMO layer includes on component from the group of Al₂O₃, HfOₓ, HfO₂, HfO, HfOₓN_{y}, HfₙOₓ, W₂O₃, WO₃, TiOₓ, TiO₂, Ti₂O₃, TaOₓ, Ta₂O₅, TaON, NiO, Nb₂O₅, MgO, CoO, WₙOₓ, TiₙOₓ, TaₙOₓ, SnO₂, ZrₓO_{y}, ZrO, GeOₓ, CeO₂, ZnO, WO, CuO₂, SrTiO₃, MoO, AlOₓN_{y}, AlₙOₓ, SiₓN_{y}.

4. The method according to claim 1, wherein the TMO layer is applied by a reactive PVD method, a reactive ALD method, or a reactive CVD method.

5. The method according to claim 1, wherein the TMO layer has a layer thickness of between 1.5 nm and 40 nm.

6. The method according to claim 5, wherein the TMO layer has a layer thickness of between 1.5 nm and 10 nm.

7. The method according to claim 1, wherein the impurity atoms implanted in the TMO layer include at least one of the group consisting of oxygen, nitrogen, Li, Be, B, C, F, Ne, Na, Mg, Al, Si, P, S, Cl, and Ar.

8. The method according to claim 1, wherein the implanted impurity atoms are introduced into the TMO layer at an energy in a range between 0.5 keV and 200 keV.

9. The method according to claim 1, wherein an ion implanter is used, the exiting ions being guided through ion optics to the TMO layer.

10. The method according to claim 9, wherein the ions exiting the ion implanter are at least partially neutralized prior to entering the TMO layer.

11. The method according to claim 1, wherein the impurity atoms introduced into the TMO layer penetrate the TMO layer at least through part of a layer thickness of the TMO layer.

12. The method according to claim 1, wherein the impurity atoms introduced into the TMO layer penetrate the TMO layer through an entire layer thickness of the TMO layer.

13. (canceled)

14. An implanter, a reactive ion etcher of an ion gun for performing the method recited in claim 1.
